(19) United States
(12) Patent Application Publication
(10) Pub. No.: US 2013/0069043 A1
(43) Pub. Date: Mar. 21, 2013

(54) Electro Optic Devices

(71) Applicants: Richard H. Friend, Cambridge (GB); Henry Snaith, Oxon (GB); Dinesh Kabra, Mumbai (IN); Myoung Hoon Song, Ulsan Metropolitan City (KR); Li Ping Lu, Cambridge (GB)

(72) Inventors: Richard H. Friend, Cambridge (GB); Henry Snaith, Oxon (GB); Dinesh Kabra, Mumbai (IN); Myoung Hoon Song, Ulsan Metropolitan City (KR); Li Ping Lu, Cambridge (GB)

(73) Assignee: CAMBRIDGE ENTERPRISE LIMITED, Cambridge (GB)

(21) Appl. No.: 13/521,692

(22) PCT Filed: Jan. 12, 2011
(86) PCT No.: PCT/GB2011/050038

§ 371 Date: Oct. 12, 2012

(30) Foreign Application Priority Data
Jan. 12, 2010 (GB) 1000453.9

(51) Int. Cl. H01L 51/52; H01L 51/56

(52) U.S. Cl. 257/40; 438/46; 257/E51.018

(57) ABSTRACT

An electro optic device comprising a first electrode and a second electrode and an emissive layer located between the first and second electrodes, the emissive layer comprising a polymeric semiconductor, or semiconducting and luminescent material having a thickness of 200 nm to 3000 nm.

The current invention relates to electro-optic devices and especially, although not exclusively, to such devices suitable for use in lighting applications.

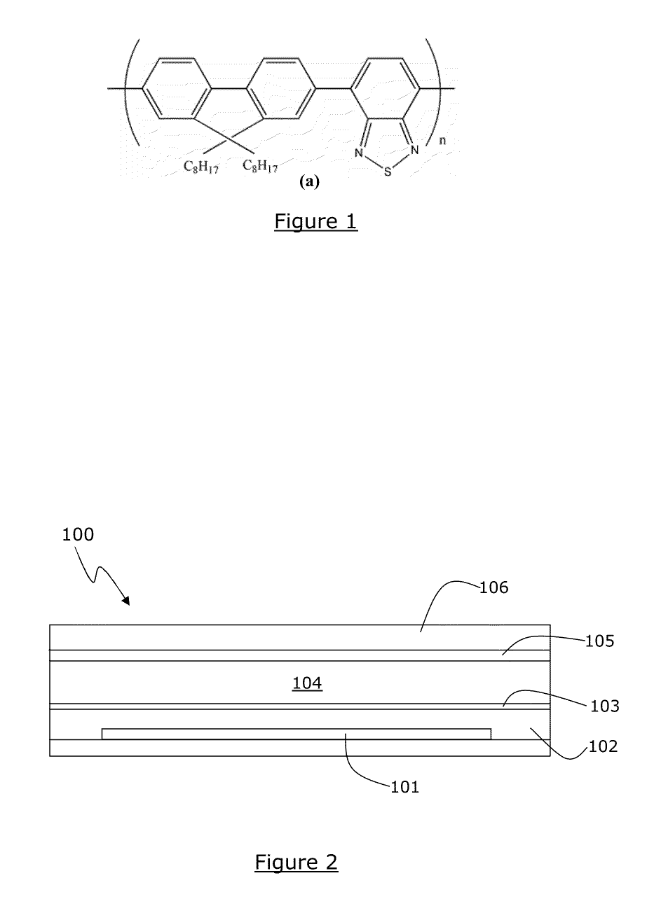

Electro-optic devices such as organic/polymeric light emitting diodes (PLEDs) have been actively investigated in recent years for display and solid state lighting due to their rapidly improving efficiency and performance¹. It has been realized for these devices that the interfaces between the electrodes and emissive semiconductors play important roles in determining their operating characteristics and stability^{2,3}. The current inventors and others have shown that ZnO can provide adequate electron injection into poly(9,9′-dioctylfluorene-co-benzothiadiazole) (F8BT)⁴⁻¹⁰. The chemical structure of which is shown in FIG. 1. Coating of ZnO with a thin layer of Cs₂CO₃ has been shown to further improve the current efficiency in hybrid PLEDs⁸. Ohmic hole injection into the deep HOMO level of F8BT (˜5.8 eV) is difficult using high work function metals or a layer of the conducting polymer Poly(3,4-ethylenedioxythiophene)poly(styrenesulfonate) (PEDOT:PSS). Recent work on hybrid PLEDs has demonstrated that MoO₃ is a potential candidate to achieve good hole injection into F8BT^{4,6,7}. It has recently been shown in photoelectron spectroscopy study that the work-function of MoO₃ is as large as 6.9 eV¹¹. This enables ohmic hole injection into materials with ionisation potentials significantly deeper than that for F8BT¹². MoO₃ has also been utilized in OLED¹³ and in transistor¹⁴ structures for improved hole injection. The prior art hybrid inverted PLED structures, as shown in FIG. 2, have metal-oxides as charge transporting and injection layers. Most of the studies in this area are focused on the bottom n-type metal-oxides layer for example compact TiO₂^{4,6}, mesoporous TiO₂^{4,9,15} ZnO^{4,5,7,18,16} and ZrO₂¹⁰ and have used a thermally evaporated p-type MoO₃ hole-injecting layer on the top surface of the polymer. Surface treatments of n-type metal-oxides have also been used to enhance electron injection and hole-blocking characteristics^{8,17}.

A conventional structure for an emissive polymer LED is to have a low work function metal as the cathode, for instance a Ca/Al bi-layer, and a high work function conducing polymer as the anode, for instance and ITO/PEDTO:PSS bi-layer.².

It is an object of the current invention to provide an electro-optic device with improved performance and/or with improved manufacturability so as to make the device easier and/or cheaper to manufacture. It is a further non-limiting object of the invention to provide devices with improved robustness over the prior art.

A first aspect of the invention provides an electro optic device comprising a first electrode and a second electrode and an emissive layer located between the first and second electrodes, the emissive layer comprising a polymeric or semiconductor material, e.g. a semiconducting and luminescent material, having a thickness of from 200 nm to 3000 nm.

The device may have a conventional or hybrid structure. Interlayers may be provided between one or other (or both) of the electrodes and the emissive layer.

The device may give luminance efficiencies of greater than 10 Cd/A for green emissive materials for a hybrid structure. The device may give luminance efficiencies of greater than 7cd/A for green emissive materials for a conventional structure.

The device may yield an EQE in excess of 4% for hybrid structures and in excess of 2% for conventional structures.

A second aspect of the invention provides a single layer polymer LED having a first electrode and a second electrode and an emissive layer of F8BT greater than 200 nm thick located between the first and second electrodes, the device comprising one or more interlayers between one or both electrodes and the emissive layer, the LED having a peak luminance efficiency of greater than 7 cd/A at a drive voltage of less than 4V and an emissive layer thickness of 200 nm and a peak luminance efficiency of greater than 15 cd/A at a drive voltage of less than 18.5V with a emissive layer thickness of about 1000 nm.

There is further provided by a third aspect of the invention, a method of forming an electro optic device, the method comprising the steps of providing a cathode on a substrate, providing an interlayer of high electron affinity on the cathode, prior to annealing the interlayer, depositing thereon an emissive layer comprising a polymeric or semiconductor material, to a thickness of from 200 nm to 3000 nm.

A further aspect of the invention provides an electro optic device comprising a first electrode and a second and an emissive layer located between the first and second electrodes the first electrode having a hole injecting material associated therewith and the emissive layer comprising a polymeric or semiconductor material having a thickness of about 1000 nm and a luminance efficiency in excess of 18 cd/A.

In order that the present invention may be more fully understood, it will now be described, by way of example only, with reference to the accompanying drawings, in which:

FIG. 1 shows the chemical structure of F8BT;

FIG. 2 shows a prior art hybrid inverted PLED architecture;

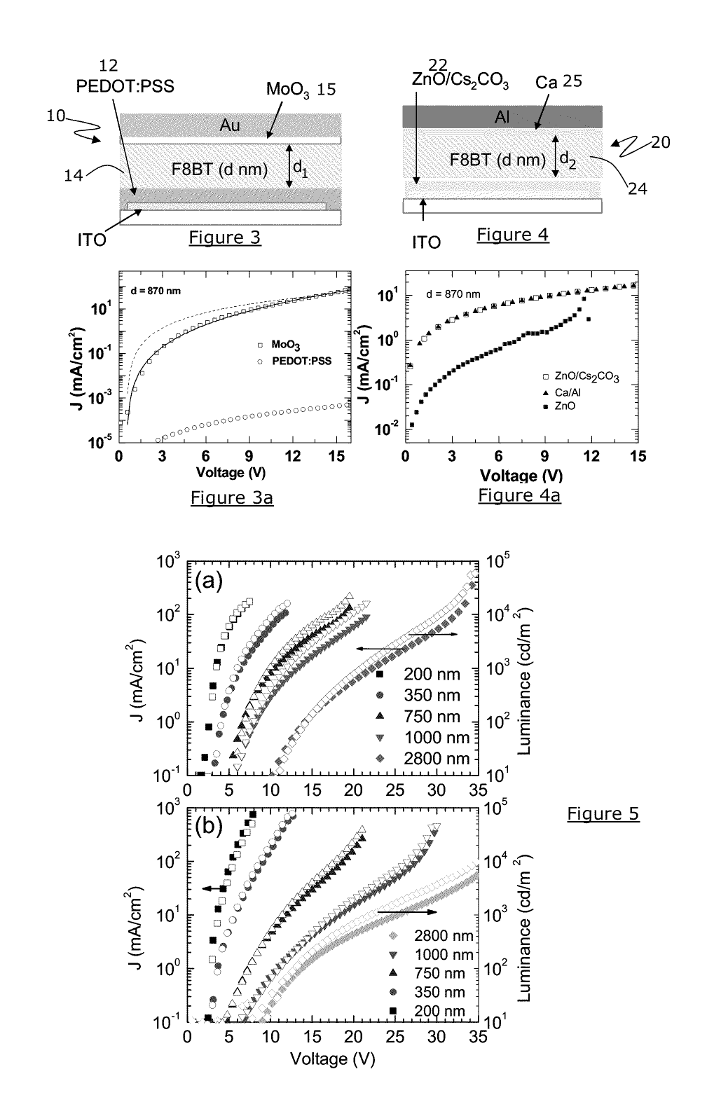

FIG. 3 shows a schematic representation of a device according to a first embodiment of the invention;

FIG. 3a is a graph showing the J-V characteristics of the first embodiment;

FIG. 4 shows a schematic representation of a device according to a second embodiment of the invention;

FIG. 4a is a graph showing the J-V characteristics of the second embodiment;

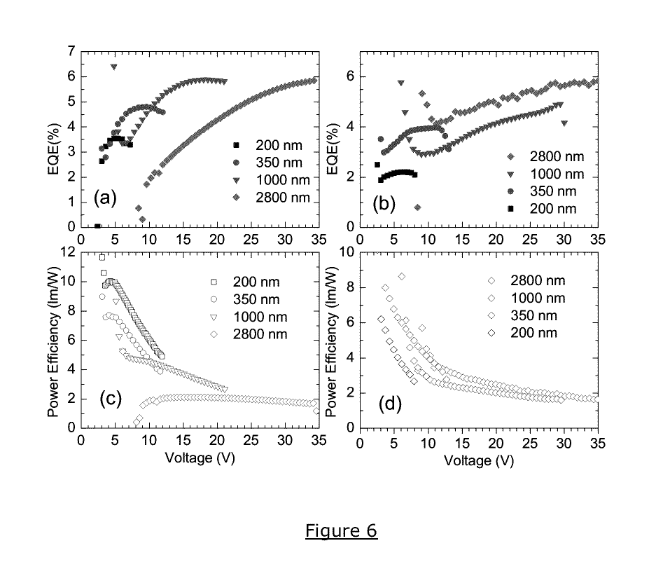

FIG. 5 is a schematic representation of a device according to a third embodiment of the invention;

FIG. 5a is a graph showing the J-V characteristics of the third embodiment;

FIG. 5b is a graph showing the J-V characteristics of a device according to a fourth embodiment of the invention;

FIG. 6a is a graph showing the External Quantum Efficiency (EQE) of the device according to the third embodiment;

FIG. 6b is a graph showing the External Quantum Efficiency (EQE) of the device according to the fourth embodiment;

FIG. 6c is a graph showing the Power Efficiency (PE) of the device according to the third embodiment; and

FIG. 6d is a graph showing the Power Efficiency (PE) of the device according to the fourth embodiment.

Referring first to FIG. 2, a prior art hybrid inverted PLED device 100 is shown which comprises a ZnO layer 102 (˜70 nm) on ITO 101, followed by a solution processed Cs₂CO₃ interlayer 103 of about ˜7 nm thickness and a spin-coated F8BT film 104 of about ˜100 nm thickness and finally a thermally evaporated MoO₃ (10 nm)/Au(50 nm) layer 105 as the top contact.

In order to understand the injection and transport mechanism of electrons and holes in these LEDs, single carrier diodes were fabricated and tested according to the following protocol.

### EXPERIMENTAL

PEDOT:PSS film (thickness ˜50 nm) was spin-coated on cleaned ITO substrates and annealed at 120° C. under inert atmosphere for 30 minutes. Oxygen plasma treatment was done in order to make hole only and conventional bipolar devices. Compact ZnO layers (˜50 nm) were fabricated by employing spray pyrolysis deposition (SPD) on ITO substrates at 350 C using a Zinc acetate dihydrate (from Fluka) in methanol (80 g/l). Cs₂CO₃ interlayer was spin-coated on the ZnO layers using ethoxy ethanol as the solvent with a concentration of 5 mg/ml at spin speed of 6000 rpm. F8BT (Mₙ=97 K) was spin-coated from a p-xylene solution with the different concentration from 5 mg/ml to 60 mg/ml to achieve a wide range of polymer thickness from 31 nm to 2856 nm. We noticed polymer deposition after annealing Cs₂CO₃ thin film diminish device performance and polymer deposition immediately after deposition of Cs₂CO₃ enhances device performance. In this specification, we are showing the results for latter processed device fabrication. All samples were annealed at 155° C. under nitrogen atmosphere to improve the morphology of the F8BT. Finally, all these samples were transferred to a thermal evaporation chamber for MoO₃ (10 nm) (powder, 99.999% from Testbourne) and Au (50 nm) deposition under high vacuum (1×10⁻⁶ mbar). For angular electroluminescence emission studies, devices were cut in such a way so that we could expose a small edge of the pixel (pixel area 3 mm×1.5 mm) away from top metal contact. A multimode optical fiber (core diameter=600 μm) coupled spectrograph (USB 4000: Ocean Optics, Inc) was used to collect emission at a distance of 15 mm from the LEDs at different angles, while keeping the devices stationary. Polymer films with thickness more than 1 m were found to adhere less well on the Cs₂CO₃ surfaces and peeled off most of the time while cutting the substrates in order to check angular emission pattern. Current density (Keithley 2400 source measurement unit) and brightness (Keithley 2000 multimeter) versus applied voltage (Keithley 2400 sourcemeter) characteristics for the LEDs were measured in air using a calibrated reference Si photodetector.

### Example 1

Hole-only diodes 10 were fabricated by replacing the electron-injecting layer 102, 103 of ZnO/Cs₂CO₃ of the conventional hybrid 100 as shown in FIG. 2, with the higher work function conducting PEDOT:PSS polymer layer 12, as shown in FIG. 3. Referring to FIG. 3a, the J-V characteristics of these hole-only devices 10, with hole-injection from the MoO₃ layer 15, show that with increasing thickness “d” of the active polymer layer 14 the current turn on voltage does not increase as would be expected from a field induced injection mechanism, but the operating voltage for a given current density does increase. The current-voltage curves for F8BT films 14 of thickness d₁=870 nm thick, injecting holes from the MoO₃ side and the PEDOT:PSS side are shown in FIG. 3a. The hole-current turn-on from injection from the MoO₃ layer 15 is in the sub volt range and the current density is up to five orders of magnitude greater than when injecting from the PEDOT:PSS electrode 12. Whilst we do not wish to be limited by any particular theory, we believe that this gives clear and remarkable evidence for facile hole injection from the MoO₃ layer 15.

J-V characteristics for different thicknesses of the F8BT layer 14 show that current densities are bulk limited rather than injection limited as we model below.

In order to describe the bulk hole conduction in F8BT 14, with hole injection from the MoO₃ layer 15, we use the Mott-Gurney space-charge-limited-current (SCLC) equation¹⁹ combined with field dependent mobility as described in detail in the literature²⁰. We use a simplified form of SCLC enhanced by the Frenkel effect²¹ as given by the following equation:

$${J}_{SCLC}^{PF} = \frac{9}{8} ɛ {μ}_{0} \frac{{V}^{2}}{{d}^{3}} exp ( β \sqrt{\frac{V}{d}} ) \qquad ( 1 )$$

Where ∈=∈₀∈ᵣ permittivity of the polymer, μ₀=the hole zero field mobility, d=thickness of polymer film, V is the applied bias (the built-in potential V_{bi}˜0.5 V subtracted from the applied voltage) and β is the field effect mobility coefficient, which depends upon trap depths in organic semiconductors. A value of β of 9×10⁻³ cm^{1/2} V^{1/2} and zero field mobilities shown in Table 1, were obtained by fitting the J-V curves of devices of different thicknesses.

TABLE 1
Hole mobility obtained from fitting of the J-V
curves for the hole-only devices with SCLC enhanced
Frenkel model for β = 9 × 10⁻³ cm^{1/2}V^{-1/2}

| Thickness (nm) | 190 | 380 | 872 | 1130 |
|---|---|---|---|---|
| Hole mobility (10⁻⁶ cm²/V − s) | 0.5 | 1.7 | 1.8 | 1.8 |

FIG. 3a also shows fitting of the MoO₃ hole injection current fitted with a field independent mobility in the SCLC model (dash line), and with the field dependent term (solid-line), which indicates that the field dependent mobility term is important. The hole mobility compares well with previously reported values for F8BT and β is found to be around one order of magnitude smaller than that reported for electron²², showing that the hole mobility is less influenced by the applied field. When the device is biased to inject the holes from PEDOT:PSS, the hole current is injection limited, this is due to high injection barrier for holes from PEDOT:PSS (work function 5.1 eV) to HOMO level (5.8 eV) of F8BT polymer.

Whilst we do not wish to be limited by any theory, we believe that there are two possible reasons for the exceptionally good hole contact from MoO₃ to F8BT:
MoO₃ is purely acting as a p-type semiconductor and the work function correctly matches F8BT to enable barrier-less hole injection.
Secondly, the thin MoO₃ layer (<10 nm) is pulling electrons from the HOMO level of the F8BT, resulting in p-type doping at this interface, which would result in an Ohmic contact between the F8BT and either the MoO₃ or directly to the Au.

### Example 2

Electron-only devices 20 were fabricated by altering the prior art hybrid architecture of FIG. 2 such that the hole-injecting layer 105 of MoO₃/Au contact is replaced with a low work function material (e.g. Ca/AI) contact 25, as shown in FIG. 4. FIG. 4a shows similar current densities for both injection of electrons from the ZnO/Cs₂CO₃ layer 22 and from the Ca layer 25 for thick polymer films (e.g. d₂=870 nm). We note that there is about factor of four lower current density for the electron-only device than for the hole-only device, as shown in FIG. 3a.

### Example 3

We also constructed electron-only devices without the Cs₂CO₃ interlayer and measured the J-V characteristics, which results are also shown in FIG. 4a. The results show that the electron current was reduced a further order of magnitude, which reveals that Cs₂CO₃ reduces the injection barrier for electrons.

According to our electron only device data, the Cs₂CO₃/F8BT interface has almost identical electron injection properties as the Ca/Al electrode, which indicates favourable interfacial charge transfer process over that reported for a F8BT/CsF/AI interface, where CsF/AI electrodes are observed to have lower electron injection efficiency than Ca/Al electrodes. The electron-only J-V characteristics shown in FIG. 4a, do not fit with well with the SCLC and Pool-Frenkel model. Nevertheless, we consider that the very similar current densities for injection from ZnO/Cs₂CO₃ and from Ca/Al indicate that the current is substantially bulk limited and therefore show the electron mobility to be a factor of 4 lower than that of the holes under this lower charge density space-charge limited regime.

### Example 4

In this example. bipolar devices 30 were studied for LEDs characterization. The typical architecture was ITO/ZnO(70 nm)/Cs₂CO₃ (7 nm)/F8BT(d₃ nm)/MoO₃ (10 nm)/Au (50 nm). The polymer layer thickness d₃ was varied from 100 nm to 3000 nm. A schematic of the device is shown in FIG. 5 and experimental J-V-L characteristics are shown in FIG. 5a and Table 2a.

### Example 5

For comparison, we also measured conventional architecture PLEDs, employing PEDOT:PSS as the hole-injecting layer and Ca/Al as the electron injecting top metallic electrode and varying the thickness d₄ of the polymer layer (e.g. of the following architecture ITO/PEDOT:PSS/F8BT (d₄ nm)/Ca/Al devices incorporating F8BT layers of different thickness), the results of which being shown in FIG. 5b and Table 2b.

In each of FIGS. 5a and 5b the solid symbols represent current density and open symbols luminance.

TABLE 2
LED performance parameters for (a) ITO/ZnO/Cs₂CO₃/F8BT(d₃
nm)/MoO3/Au hybrid & (b) ITO/PEDOT: PSS/F8BT(d₄
nm)/Ca/Al conventional structures.

| | | | | |
|---|---|---|---|---|
| 200 nm | 350 nm | 750 nm | 1000 nm | 2800 nm |

a: Hybrid PLEDs parameters (See Example 4)

| | | | | | |
|---|---|---|---|---|---|
| Hybrid LED | | | | | |
| Bias @ 10 mA/cm² | 3.4 V | 6.3 V | 10.5 V | 13.2 V | 22.3 V |
| Bias @ 1000 cd/m² | 3.5 V | 5.9 V | 9.9 V | 11.8 V | 21 V |
| Peak Luminance | 11 | 15 | 16.8 | 18.2 | 18.4 |
| Efficiency (cd/A) | | | | | |
| Peak EQE (%) | 4.6 | 6.2 | 7.5 | 7.7 | 7.8 |

b: Conventional PLEDs parameters (See Example 5)

| | | | | | |
|---|---|---|---|---|---|
| Conventional. LED | | | | | |
| Bias@ 10 mA/cm² | 3.6 V | 5.8 V | 11.9 V | 18.3 V | 25.3 V |
| Bias@ 1000 cd/m² | 3.8 V | 5.7 V | 11.5 V | 17.6 V | 22.1 V |
| Peak Luminance | 7.1 | 12.8 | 14.7 | 15.4 | 18.3 |
| Efficiency (cd/A) | | | | | |
| Peak EQE(%) | 2.3 | 4.0 | 4.7 | 5.0 | 5.9 |

We observe the operating voltages to gradually increase with increasing thickness of the polymer, e.g. F8BT, layer, but the offset between current turn-on and light turn-on is small and the luminance curves follows the current curves. This indicates injected carriers recombine efficiently and the luminous efficiency is weekly dependent on applied voltage. The luminance was collected as forward emission, as shown in FIGS. 5a, b, on the basis that the emission is lambertian. However, we believe that the emission pattern from the devices of the invention is likely to exhibit significant deviations from lambertian emission from our angular emission pattern studies in ‘thin’ conventional PLEDs.

Referring now to FIGS. 6a to 6d, the external quantum efficiency and power efficiency curves are shown respectively for the embodiment of Example 4 (FIGS. 6a and 6c) and for the embodiment of Example 5 (FIGS. 6b and 6d) at different thickness of polymer (e.g. F8BT) layers.

We observe that for conventional devices (e.g. Example 5), with increasing the thickness of the F8BT layer, the peak efficiency operating voltages are increased, which is consistent with the poorer hole-injection and lower electron mobility in the single carrier devices. However, the embodiment of Example 5 also showed improved quantum efficiencies for thicker devices. These devices also give an optimum thickness of the F8BT layer in single layer LED geometry of more than 1 μm.

We observe that on changing the thickness of the polymer (e.g. F8BT) layer, there is no significant change in the electroluminescence (EL) spectrum. This indicates that the recombination zone remains at a similar position in the device (which we consider to be close to the cathodes for the embodiment of Example 4 (and other ‘hybrids’) and close to anode for the embodiment of Example 5 (and other ‘conventional’ structures) and allows us to use the luminous efficiency presented in Table 2 to follow the effects of changing the thickness of the F8BT.

Optical losses studies with different architecture reveals the advantage of recombination zone near to lossless cathode as compare to conventional structures, as shown in Table 3.

TABLE 3
Optical losses characterization by photoluminescence quantum
efficiency measurement for different interfaces with emissive
F8BT polymer, on excitation with 488 nm laser source.

| Architecture | PLQE (%) |
|---|---|
| F8BT | 76 |
| ITO/F8BT | 46 |
| ITO/PEDOT: PSS/F8BT | 36 |
| ITO/ZnO/F8BT | 57 |
| ITO/ZnO/Cs₂CO₃/F8BT | 54 |

External quantum efficiency (EQE) and power efficiency are also measured for hybrid devices, as shown in FIG. 6 and Table 2. Highest EQE was found for optimum thickness and it remains almost the same for devices thicker than the recombination zone. However, the power efficiency is lower for thicker devices due to of the higher operating voltages. We note that for a given current density the voltages for these structures are set by the bulk hole mobility, and that materials with higher mobilities that we measure for F8BT may well allow drive voltages to be reduced.

For the hybrid bipolar devices, the bi-polar current-voltage characteristics are comparable to the hole-only diodes. This demonstrates that the current in the LED is not limited by the unipolar electron transport. If we consider ohmic injection of holes, with a high current, then these will rapidly drift across the film and build up at the electron injecting interface. This will redistribute the electric field at Cs₂CO₃/F8BT interface and thus enhance the injection rate for electrons. We therefore expect a large fraction of the electron-hole recombination to be near to the cathode interface. This is desirable since there is very little exciton quenching at the ZnO/Cs₂CO₃-polymer interface (see Table 3).

For conventional structures, improved efficiencies can be explained by adequate electron injection properties, which redistribute electrical field near to anode interface and reduces injection barrier for holes. In our studies also we found conventional structure bipolar device J-V characteristics closely follow electron only devices and for 1 μm devices we do see factor of 4 higher bipolar current for hybrid devices than conventional bipolar devices (current densities @13 V), which is in consistent with single carrier devices studies. However, the optimum LED thickness is as high as ˜1 μm, indicating that the recombination zone extends over this length scale.

We note that a balanced electron and hole mobilities under the spaced charge regime may result in devices with emissive polymeric layers which are many microns thick. We postulate that the useful range of thicknesses is likely to be in the range of from 200 nm to 4 microns, for example from 200 nm to 3000 nm, say 300 to 1500 nm, and most probably between 600 nm and 1400 nm. Whilst we have exemplified our invention using the well known polymer F8BT it is well within the ambit of the skilled person to substitute the polymer or some of it to provide a different, blended composite or laminate emissive layer. For example, poly((9,9-dioctylfluorene)-2,7-diyl-alt-[4,7-bis(3-hexylthien-5-yl)-2,1,3-benzothiadiazole]-2,2-diyl) (F8TBT) can be used as a total or partial substitute for at least some of the F8BT. Other emissive species may be used.

In summary, MoO₃ provides an unprecedented ohmic contact to the high ionization potential polymer F8BT. This facilitates bright and efficient single polymer layer LEDs with peak efficiency of 18.5 Cd/A at thickness of around 1 μm. This is approximately 10 times thicker than standard LEDs. This device geometry is more advantageous in terms of fabrication cost and performance, industrially the ability to make micron thick active layers is extremely attractive since it should significantly increase reproducibility, film conformity and reduce the occurrence of shorts and black-spots. Conventional devices also found to be significantly efficient with thick layer of F8BT, due to high electron current from Ca/Al. We have also demonstrated the role of charge injection efficacy and mobility in making OLEDs with thick emissive layers, which is also advantageous for making optically pumped organic laser and future electrically injectable organic diode lasers.

### REFERENCES

1. S. Reineke, F. Lindner, G. Schwartz, N. Seidler, K. Walzer, B. Lussem and K. Leo Nature 2009, 459, 234.
2. P. K. Ho, J. S. Kim, J. H. Burroughes, H. Becker, S. F. Y. Li, T. M. Brown, F. Cacialli and R. H. Friend, Nature 2000, 404, 481.
3. J. S. Kim, R. H. Friend, I. Grizzi and J. H. Burroughes, Appl. Phys Lett. 2005, 87, 023506.
4. D. Kabra, M. H. Song, B. Wenger, R. H. Friend and H. J. Snaith Adv Mater. 2008, 20, 3447.
5. M. H. Song, D. Kabra, B. Wenger, R. H. Friend and H. J. Snaith Adv. Func. Mater. 2009, 19, 2130.
6. K. Morii, M. Ishida, T. Takashima, T. Shimoda, Q. Wang, M. K. Nazeeruddin, M. Gritzel, Appl. Phys. Lett. 2006, 89, 183510.
7. H. J. Bolink, E. Coronado, D. Repetto, M. Sessolo, Appl. Phys. Lett. 2007, 91, 223501.
8. H. J. Bolink, E. Coronado, J. Orozco, and M. Sessolo, Adv. Mater. 2009, 21, 79.
9. S. A. Haque, S. Koops, N. Tokmoldin, J. R. Durrant, J. Huang, D. D. C. Bradley, E. Palomares, Adv. Mater. 2007, 19, 683.
10. N. Tokmoldin, N. Griffiths, D. D. C. Bradley, and S. A. Haque, Adv. Mater. 2009, 21, 1.
11. M. Krögera, S. Hamwib, J. Meyerb, T. Riedlb, W. Kowalskyb and A. Kahn, Org Elecs, 2009 10, 932.
12. Y. Nakayama, K. Morii, Y. Suzuki, H. Machida, S. Kera, N. Ueno, H. Kitagawa, Y. Noguchi and H. Ishii, Adv Func. Mater. 2009, 19, 1.
13. H. You, Y. dai, Z. Zhang, D. Ma, J. Appl. Phys. 2007, 101, 026105.
14. C.-W. Chu, S-H. Li, C-W. Chen, V. Shrotriya, Y. Yang, Appl. Phys. Lett. 2005, 87, 193508.
15. K. Lee, J. Y. Kim, S. H. Park, S. H. Kim, S. Cho, A. J. Heeger, Adv. Mat. 2007, 19, 2445.
16. H. J. Bolink, E. Coronado and M. Sessolo, Chem. Mater. 2009, 21, 439.
17. K. Morii, T. Kawase, and S. Inoue, Appl. Phys. Lett. 2008, 92, 213304.
18. K. Murata, S. Cina, N. C. Greenham Appl. Phys. Lett. 2001, 79, 1193.
19. M. A. Lambert, P. Mark, Current injection in solids, Academic Press, New York, 1970.
20. W. F. Pasveer, J. Cottaar, C. Tanase, R. Coehoorn, P. A. Bobbert, P. W. M. Blom, D. M. de Leeuw and M. A. Michels, Phys. Rev. Lett. 2005, 94, 206601.
21. R. I. Frank and J. G. Simmons, J. Appl. Phys. 1967, 38, 832.
22. K. J. Reynolds, J. A. Barker, N. C. Greenham, R. H. Friend and G. L. Frey, J. Appl. Phys. 2002, 92, 7556.

1. An electro optic device comprising a first electrode and a second electrode and an emissive layer located between the first and second electrodes, the emissive layer comprising a polymeric semiconductor, or semiconducting and luminescent material having a thickness of from 200 nm to 3000 nm.

2. A device according to claim 1, wherein the emissive layer has a thickness of from 300 nm to 1500 nm.

3. A device according to claim 1, wherein the anode is a metal oxide with a high ionization potential.

4. A device according to claim 3, wherein the anode is selected from the group consisting of MoO₃, WO₃, NiO, and V₂O₅.

5. A device according to claim 1, wherein the cathode comprises a metal oxide with a high electron affinity.

6. A device according to claim 5, wherein the cathode has a low dielectric constant.

7. A device according to claim 1, wherein the cathode is selected from the group consisting of ZnO, TiO₂, SnO₂, ZrO₂, and ZnO nanorods.

8. A device according to claim 1, wherein the mobility of the more mobile charge carrier (electron or hole) in the emissive layer exceeds 10⁻⁶ cm²/Vs.

9. A device according to claim 1, further comprising an interlayer of a high electron affinity compound.

10. A device according to claim 8, wherein the interlayer comprises one or more member selected from the group consisting of Cs₂CO₃, barium acetate dehydrate, calcium acetylacetonate, and self-assembled polymer monolayers.

11. A device according to claim 1, wherein the emissive layer comprises one or more member selected from the group consisting of F8BT, F8TBT, and other emissive polymeric species.

12. A device according to claim 1, wherein the device has a current density of more that 10 mA/cm² at 3.8V for an emissive layer of greater or equal to 350 nm thickness.

13. A device according to claim 1, wherein the emissive layer has a thickness in excess of 350 nm and the device has a peak EQE of 4% or greater.

14. A device according to claim 1, wherein the emissive layer has a thickness in excess of 200 nm and a peak luminance efficiency of greater than 7 Cd/A.

15. A method of forming an emissive optoelectronic device, the method comprising:
providing a cathode on a substrate,
providing an interlayer of high electron affinity on the cathode, and
depositing thereon an emissive layer comprising a polymeric or semiconductor material, to a thickness of from 200 nm to 3000 nm.

16. A method according to claim 15 comprising annealing the interlayer after depositing the emissive layer.

17. (canceled)

18. (canceled)

19. A device according to claim 1, wherein the emissive layer has a thickness of between 800 nm and 1200 nm.

20. A device according to claim 1, wherein the emissive layer has a thickness of about 1000 nm.

21. A device according to claim 5, wherein the cathode has a dielectric constant less than 10.
